(19) United States
(12) Patent Application Publication
(10) Pub. No.: US 2002/0000852 A1
(43) Pub. Date: Jan. 3, 2002

(54) RESET CIRCUIT

(76) Inventor: MASAFUMI NAGAYA, MIYAZAKI-SHI (JP)

Correspondence Address: ROBERT J. FRANK, VENABLE, BAETJER, HOWARD & CIVILETTI, P O BOX 34385, WASHINGTON, DC, 200439998

(21) Appl. No.: 09/239,996

(22) Filed: Jan. 29, 1999

(30) Foreign Application Priority Data
Jan. 29, 1998 (JP) 17409/98

(51) Int. Cl. H03K 17/22

(52) U.S. Cl. 327/143

(57) ABSTRACT

The reset circuit comprises the P-channel MOS transistor 10, the resistive element 30, the N-channel MOS transistor 50, and the resistive element 40. One electrode of the P-channel MOS transistor 10 is supplyed a source voltage VDD, and other electrode and the gate electrode thereof is connected to the node 20. One node of the resistive element 30 is connected to the node 20, and other node thereof is supplyed the ground voltage VSS. One electrode of the N-channel MOS transistor 50 is connected to the output node 60, gete electrode thereof connected to the node 20, and other electrode thereof is supplyed the ground voltage VSS. One node of resistive element 40 is supplyed the source voltage VDD, and other node thereof is connected to the output node 60.

### BACKGROUND OF THE INVENTION

1. Field of the Invention

This invention relates to a reset circuit incorporated into a electronic equipment and outputting a reset signal to reset a internal circuit in the electronic equipment after power-on.

2. Description of the Related Art

A semiconductor device is incorporated into electronic equipment, such as desk-top equipments (parsonal computer etc.) or portable equipments (portable telephone etc.). These equipments are act power-on/off. After power on, it is necessary for these equipments to turn back the starting condition to the semiconductor device in each electronic equipment, because of normally operatting of the electronic equipment. Therefore the electronic equipment or the semiconductor device in the electronic equipment have a reset circuit.

The reset circuit wacthes the change of a supply voltage according to power-on. The reset circuit outputs a reset signal temporality when the reset circuit is sensed the change of the supply voltage regard as power-on. The semiconductor device in the electronic equipment receives to the reset signal and turns back the starting condition (hereinafter also called “reset state”) to itself.

For portable equipments, each portable equipments supplyes a supply voltage from battery such as cell. The battery is incorporated into the portable equipment or is able to remove. For the electronic equipment such as portable equipment, The supply voltage unexpectedly reduces due to misdisconnection of a removable battery or the discharge of electrical charges stored in a battery put on charge in operation to the electronic equipment. Such circumstances, the reset circuit is effective to restore the operation of the electronic equipment at high speed.

The semiconductor device is reset for itself by the reset signal from the reset circuit. The reset signal has a ground voltage level or a source voltage level. The voltage level of the reset signal well result the source voltage level at one time after power-on. The semiconductor device is reset correspondance with the source voltage level of the reset signal.

However, the semiconductor device comprises CMOS comprising circuit (hereinafter also called “CMOS circuit”) such as flip-flop circuit and latch circuit. The lowest operating voltage at which the CMOS circuit normally operates is about |VTP|+VTN=VDD. VTP is threshold voltage of P-channel MOS transistor, VTN is threshold voltage of N-channel MOS transistor, and VDD is the source voltage. It is nessecally to assure till the lowest operating voltage at which a CMOS circuit normally operates, a period in which a source voltage level of the reset signal is maintained.

The reset circut only operates immediately after power-on or after reducing the source voltage VDD. Therefore the reset circuit is desirable to comprise a less number of components, to reduce in cost thereof, to reduce in the size of the thereof, or to improve in the degree of freedom of the lyayout of thereof.

An object of the present invention is to provide the reset circuit for reliably resetting a semiconductor device.

A further object of the present invention is to provide the reset circuit for desirabling to comprise a less number of components, to reduce in cost thereof, to reduce in the size of the thereof, or to improve in the degree of freedom of the lyayout of thereof.

### SUMMARY OF THE INVENTION

A reset circuit of the present invention for sensing to change a level of a supply voltage from a first voltage level to a second voltage level, and for outputting a reset signal from a output node, the supply voltage supplyed a supply voltage source, the reset circuit comprising a first MOS transistor of a first conductive type coupled between said supply voltage source and a control node, the first MOS transistor controlling electlically conductive state between the supply voltage source and the control node corresponding to a voltage level of the control node, a resistive element coupled between said control node and a reference voltage source, a second MOS transisitor of a second conductive type coupled between said output node and said reference voltage source, the second MOS transistor controlling electlically conductive state between the output node and the reference voltage source corresponding to a voltage level of the control node, and a third MOS transistor of said first conductive type coupled between said supply voltage source and said output node, the third MOS transistor controlling electlically conductive state between the supply voltage source and a output node corresponding to a voltage level of the control node.

Typical ones of various inventions of the present application have been shown in brief. However, the various inventions of the present application and specific configurations of these inventions will be understood from the following description.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a circuit diagram showing a reset circuit according to a first embodiment of the present invention;

FIG. 2 is a waveform chart for describing the operation of the reset circuit shown in FIG. 1;

FIG. 3 is a circuit diagram illustrating a reset circuit according to a second embodiment of the present invention; and

FIG. 4 is a waveform chart for describing the operation of the reset circuit shown in FIG. 3.

### DETAILED DESCRIPTION OF THE PREFERRED EMBODIMENTS

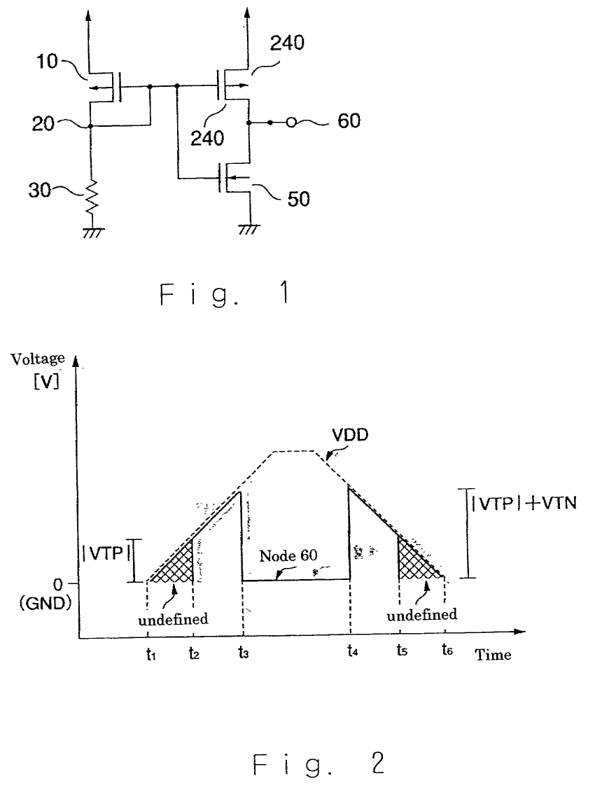

Reset circuits of the present invention will hereinafter be described in detail with reference to the accompanying drawings. FIG. 1 is a circuit diagram of a reset circuit 200 according to a first embodiment of the present invention.

Referring to FIG. 1, the reset circuit 200 comprises three transistors 10, 50, 240 and a resistive element 30.

The transistor 10, which serves as a first MOS transistor, is a P-channel MOS transistor. A source electrode of the transistor 10 is supplied with a source voltage VDD from a supply voltage source or voltage source. Further, drain and gate electrodes thereof are electrically connected to a node 20 which serves as a control node. The resistive element 30 has one terminal electrically connected to the node 20 and the other terminal electrically grounded to a reference voltage source. Thus, the other terminal of the resistive element 30 is supplied with a ground voltage VSS from the reference voltage source. Incidentally, the threshold voltage of the transistor 10 will be defined as V_{TP}.

The transistor 50, which serves as a second MOS transistor, is an N-channel MOS transistor. A drain electrode of the transistor 50 is electrically connected to an output node 60, a gate electrode thereof is electrically connected to the node 20, and a source electrode thereof is electrically grounded. The threshold voltage of the transistor 50 will be defined as V_{TN}.

The transistor 240, which serves as a third MOS transistor, is a P-channel MOS transistor. A source electrode of the transistor 240 is supplied with the source voltage VDD. A drain electrode of the transistor 240 is electrically connected to the output node 60, and a gate electrode thereof is electrically connected to the node 20. Therefore, the transistors 10 and 240 constitute a current mirror circuit. The threshold voltage of the transistor 240 will be defined as V_{TP}. A change in the value of a voltage developed at the output node 60 is utilized as a reset signal for the reset circuit 200.

Incidentally, the source voltage VDD employed in the reset circuit 200 includes, as supply voltage sources, for example, one supplied from the outside of electronic equipment, one supplied from a battery such as a cell or the like incorporated into electronic equipment. Various types or forms are known as supply sources for the reset circuit 200. In particular, the battery may be a chargeable type or may be removable from the electronic equipment.

Even if the resistive element 30 is placed in any configuration, the resistance value of the resistive element 30 is set so as to be sufficiently higher than an on resistance of the transistor 10.

The operation of the reset circuit 200 constructed in this way will be described below with reference to the drawings. FIG. 2 is a waveform chart for describing the operation of the reset circuit 200. In FIG. 2, the vertical axis indicates the voltage and the horizontal axis indicates time. A solid line indicates the value of a voltage developed at the output node 60 from which a reset signal is outputted, and a dotted line indicates the value of the source voltage VDD. The relationship between VTP and VTN will be explained as |VTP|>VTN in the following description. Prior to power-on, any of the transistors 10, 50 and 240 will be kept in an off state (i.e., there is electrically non-continuity between their sources and drains). Further, any of the voltage values of the source voltage VDD, the node 20 and the output node 60 will be defined as a reference voltage VSS.

When power is turned on at time t1 in FIG. 2, the value of the source voltage VDD starts to increase based on a time constant held by the power. When the source voltage VDD is given as VDD<|VTP| immediately after power-on, the transistor 10 is in the off state. Therefore, the node 20 is set to the reference voltage VSS through the resistive element 30. Thus, the transistor 50 is kept in the off state. Since the transistor 240 is placed under the same condition as that for the transistor 10, it is held in the off state. Accordingly, the value of the voltage developed at the output node 60 is undefined (held in a high-resistance state).

Thereafter, when |VTP| VDD<VTN, the transistor 10 is brought to an on state. Thus, the value of the voltage at the node 20 results in VDD−|VTP|. At this time, the transistor 240 is also turned on. Since the value of the voltage applied to the gate of the transistor 50 is given as VDD−|VTP| (<VTN), the transistor 50 is in the off state. Accordingly, the voltage value of the output node 60 results in VDD (at time t2). Incidentally, if the transistors 10 and 240 constitute the current mirror circuit and are identical to each other in transistor characteristic, the same amount of current as the transistor 10 flows in the transistor 240.

Thereafter, when VDD |VTP|+VTN, the voltage value of the node 20 results in VDD−|VTP| (VTN) and hence the transistor 50 is turned on. Therefore, the output node 60 is grounded via the transistor 50. Thus, the voltage value of the output node 60 is brought to the reference voltage VSS. Time t3 indicates timing provided immediately after VDD |VTP|+VTN.

When the source voltage VDD is lowered, the reset circuit 200 enters into operation opposite to the above operation. Therefore, when VDD<|VTP|+VTN, the output node 60 changes from the reference voltage VSS to the source voltage VDD. In FIG. 2, time t4 indicates timing provided immediately after VDD<|VTP|+VTN.

Thus, when the node 20 is used as a control node for controlling the operation of the transistor 50 and a semiconductor device built in electronic equipment is reset according to the state of the source voltage VDD of the output node 60, which is outputted as a reset signal, a period in which a source potential level of the reset signal is maintained, is assured till the lowest operating voltage at which a CMOS circuit normally operates. Thus, even if the CMOS circuit exists in the semiconductor device supplied with the reset signal, the semiconductor device can be reliably reset.

Further, since the reset circuit 200 comprises a less number of components, a reduction in cost thereof, a reduction in the size of the semiconductor device itself and an improvement in the degree of freedom of the layout of the reset circuit can be expected.

Although the relationship between VTP and VTN has been explained as |VTP| VTN as mentioned above, the operation of the reset circuit slightly differs from the above-described operation in the following points when |VTP|<VTN.

Namely, the operation thereof at VDD<VTP is similar to the above description. Thereafter, when |VTP| VDD<VTN and VTN VDD |VTP|+VTN, the transistor 10 is turned on so that the voltage value of the node 20 is raised. Since, however, the voltage value of the node 20 is represented as VDD−|VTP| (<VTN), the transistor 50 is kept in an off state. Thus, the voltage value of the output node 60 will result in the source voltage VDD. Thereafter, the operation thereof from VDD>|VTP|+VTN is similar to the aforementioned description.

If the reset circuit 200 of the present invention is applied to, for example, cellular or portable electronic equipment after power-on, then a semiconductor device incorporated into the electronic equipment can be reliably reset and the operation of the electronic equipment can be restored at high speed where the source voltage VDD is unexpectedly reduced due to misdisconnection of a removable battery or the discharge of electrical charges stored in a battery put on charge.

Since the transistor 10 and the transistor 240 constitute the current mirror circuit in the reset circuit 200, the mutual conductance gm between the transistor 10 and the transistor 240 can be adjusted so as to reduce currents which constantly flow in the transistors 10 and 50, whereby current consumption can be reduced. Since the transistor 240 is used as the resistive element, the area of the reset circuit can be reduced.

In the reset circuit 200, the reset signal outputted from the output node 60 may be supplied to respective circuits to be reset through two inverters. Theses inverters comprise a P-channel MOS transistor and an N-channel MOS transistor respectively.

More specifically, a reset signal outputted from the output node 60 is supplied to gate electrodes of two transistors which constitute a first inverter. One electrode of a P-channel MOS transistor, which constitutes the first inverter, is supplied with the source voltage VDD. One electrode of an N-channel MOS transistor, which constitutes the first inverter, is supplied with the reference voltage VSS. The other electrodes of the two transistors, which constitute the first inverter, are electrically connected to one another. A signal outputted from the first inverter becomes a signal transmitted to the other electrodes of these transistors. The signal outputted from the first inverter is supplied to gate electrodes of two transistors, which constitute a second inverter. One electrode of a P-channel MOS transistor, which constitutes the second inverter, is supplied with the source voltage VDD, and one electrode of an N-channel MOS transistor, which constitutes the second inverter, is supplied with the reference voltage VSS. The other electrodes of the two transistors, which constitute the second inverter, are electrically connected to one another. A signal outputted from the second inverter becomes a signal transmitted to the other electrodes of these transistors. The output signal of the second inverter will result in a reset signal used for each circuit.

Owing to such a construction, the level of the voltage at the output node 60 can be further amplified when the voltage level thereof increases. In a state in which the source voltage VDD has risen sufficiently, the voltage level of the reset signal supplied to each circuit can be set to an L level more reliably. Thus, the effects of the present invention can be obtained more reliably.

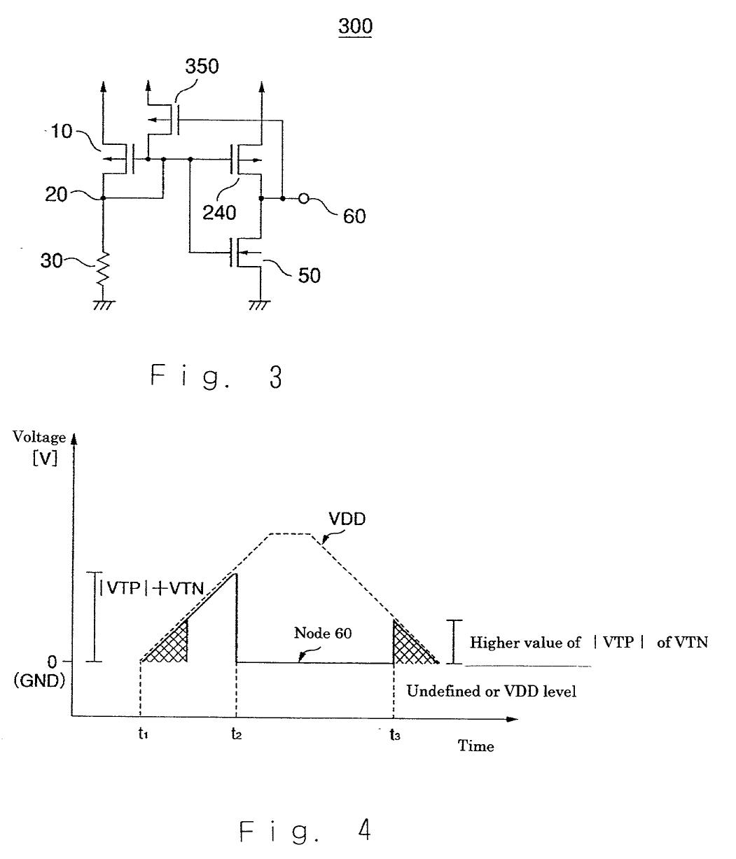

A reset circuit according to a second embodiment of the present invention will next be described below with reference to the drawings. FIG. 3 is a circuit diagram of a reset circuit 300 according to the second embodiment. In FIG. 3, the same elements of structure as those illustrated in the reset circuit 200 according to the first embodiment shown in FIG. 1 are identified by the same reference numerals.

Referring to FIG. 3, transistors 10, 50 and 240 and a resistive element 30 are similar to those employed in the reset circuit 200 shown in FIG. 1. Namely, the reset circuit 300 shown in FIG. 3 is constructed in such a manner that a P-channel MOS transistor 350 used as a fourth MOS transistor is further added to the reset circuit 200 shown in FIG. 1.

The transistor 350 has a source electrode supplied with a source voltage VDD, a drain electrode electrically connected to a node 20 and a gate electrode electrically connected to an output node 60.

The operation of the reset circuit 300 constructed in this way will be described below with reference to the drawings. FIG. 4 is a waveform chart for describing the operation of the reset circuit 300. In FIG. 4, the vertical axis indicates the voltage and the horizontal axis indicates time. A solid line indicates the value of a voltage developed at the output node 60 and a dotted line indicates the value of the source voltage VDD. Incidentally, the relationship between VTP and VTN is set as |VTP|<VTN in the reset circuit according to the second embodiment.

Since the transistors 10, 240 and 350 are placed under the same condition till VDD<|VTP|+VTN (till time t2) after power-on, the present embodiment is similar to the first embodiment.

When VDD |VTP|+VTN, the transistor 50 is brought to an on state according to the value of a voltage at the node 20. Thus, the value of the voltage at the output node 60 will result in a reference voltage VSS. Time t3 shown in FIG. 4 indicates timing provided when VDD |VTP|+VTN.

As the voltage value of the output node 60 becomes the reference voltage VSS, the transistor 350 is completely turned on. When the resistance value of the resistive element 30 is set so as to become sufficiently higher than an on resistance of the transistor 350 at this time, the voltage value of the node 20 is set to the source voltage VDD. Thus, the transistors 10 and 240 both change from an on state to an off state.

A description will be made of the case in which the value of the source voltage VDD is reduced for some reason subsequent to the above state.

Since the gate electrode of the transistor 50 is supplied with the source voltage VDD and the gate electrode of the transistor 350 is supplied with the reference voltage VSS, no changes occur in the on/off states of the respective transistors in the relationship of VDD (I VTP or a higher value of VTN) (immediately before time t3 in FIG. 4). Therefore, the voltage value of the output node remains at the reference voltage VSS.

When VDD<|VTP| in the case of |VTP| VTN, the transistor 350 changes from the on state to the off state. Therefore, the voltage value of the node 20 reaches the reference voltage VSS and correspondingly the transistor 50 is also turned off. Thus, the output node 60 is undefined (held in a high-resistance state).

On the other hand, when |VTP| VDD<VTN in the case of |VTP|<VTN, the transistor 50 changes from the on state to the off state. Thus, the transistors 10 and 240 are turned on. Therefore, the voltage value of the output node 60 changes from the reference voltage VSS to the source voltage VDD.

As described above, the reset circuit 300 according to the second embodiment can bring about an effect similar to that obtained by the reset circuit 200 according to the first embodiment referred to above.

Further, the reset circuit 300 according to the second embodiment can turn off the transistors 10 and 240 after the voltage value of the output node 60 has been brought to the reference voltage VSS. Thus, when the reset circuit is held in a steady state (corresponding to a state of being stably supplied with the source voltage VDD to activate the semiconductor device stably), a current, which flows in each of the transistors 10 and 240 of the reset circuit 300, can be interrupted. As a result, the current to be used up or consumed by the reset circuit can be reduced.

In the second embodiment, the voltage value of the output node 60 can follow VDD to reach VDD |VTP|+VTN when the source voltage VDD rises. On the other hand, when the source voltage VDD drops, the voltage value of the output node 60 can be maintained at the reference voltage VSS till VDD<|VTP|+VTN. Therefore, even when a voltage variation occurs in the source voltage VDD due to noise or the like when the semiconductor device being placed in the steady state is in operation, it is possible to exert control on a change of the voltage value of the output node into the source voltage VDD. It is thus possible to restrain the semiconductor device from being erroneously reset.

The signal outputted from the reset circuit according to the second embodiment may be used as a reset signal for each circuit to be reset through two inverters in a manner similar to the first embodiment.

Although the reset circuit of the present invention has been described above in detail, the reset circuit of the present invention is not necessarily limited to the aforementioned configuration. Various modifications can be made thereto.

The reset circuit may be utilized so that, for example, the N-channel MOS transistor and the P-channel MOS transistor are set in reverse and the portions for supplying the reference voltage VSS and the source voltage VDD act in reverse.

The threshold voltages of the respective transistors may be controlled for the lowest operating voltage of a circuit to be reset by the reset signal outputted from the output node so as to obtain the effects of the present invention more reliably.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. A reset circuit for sensing to change a level of a supply voltage from a first voltage level to a second voltage level, and for outputting a reset signal from a output node, the supply voltage supplyed a supply voltage source, the reset circuit comprising:
a first MOS transistor of a first conductive type coupled between said supply voltage source and a control node, the first MOS transistor controlling electlically conductive state between the supply voltage source and the control node corresponding to a voltage level of the control node;
a resistive element coupled between said control node and a reference voltage source;
a second MOS transisitor of a second conductive type coupled between said output node and said reference voltage source, the second MOS transistor controlling electlically conductive state between the output node and the reference voltage source corresponding to a voltage level of the control node; and
a third MOS transistor of said first conductive type coupled between said supply voltage source and said output node, the third MOS transistor controlling electlically conductive state between the supply voltage source and a output node corresponding to a voltage level of the control node.

2. A reset circuit accoding to claim 1, said reset circuit further comprises a fourth MOS transistor of said first conductive type coupleed between said supply voltage source and said control node, the fourth MOS transistor controlling electlically conductive state between the supply voltage source and a control node corresponding to a voltage level of the output node.

3. A reset circuit according to claim 1, the reset circuit incorporated into electronic equipment, a voltage of said supply voltage source supplyed a battery being removable from the electronic equipment.

4. A reset circuit according to claim 2, the reset circuit incorporated into electronic equipment, a voltage of said supply voltage source supplyed a battery being removable from the electronic equipment.

5. A reset circuit according to claim 1, said reset signal suppling a circuit to be reset through two inverters.

6. A reset circuit for sensing to change a level of a supply voltage, and for outputting a reset signal from a output node, the supply voltage supplyed a supply voltage source, the reset circuit comprising:
a first P-channel MOS transistor coupled between said supply voltage source and a control node, the first P-channel MOS transistor controlling electlically conductive state between the supply voltage source and the control node corresponding to a voltage level of the control node;
a resistive element coupled between said control node and a reference voltage source;
a N-channel MOS transistor coupled between said output node and said reference voltage source, the N-channel MOS transistor controlling electlically conductive state between the output node and the reference voltage source corresponding to a voltage level of the control node; and
a second P-channel MOS transistor coupled between said supply voltage source and said output node, the second P-channel MOS transistor controlling electlically conductive state between the supply voltage source and a output node corresponding to a voltage level of the control node.

7. A reset circuit accoding to claim 6, the reset circuit further comprises a third P-channel MOS transistor coupled between said supply voltage source and said control node, the third P-channel MOS transistor controlling electlically conductive state between the supply voltage source and a control node corresponding to a voltage level of the output node.

8. A reset circuit according to claim 6, the reset circuit incorporated into electronic equipment, a voltage of said supply voltage source supplyed a battery being removable from the electronic equipment.

9. A reset circuit according to claim 7, the reset circuit incorporated into electronic equipment, a voltage of said supply voltage source supplyed a battery being removable from the electronic equipment.

10. A reset circuit according to claim 6, said reset signal suppling a circuit to be reset through two inverters.
